(19) United States
(12) Patent Application Publication
(10) Pub. No.: US 2008/0267077 A1
(43) Pub. Date: Oct. 30, 2008

(54) Real-Time Internet Error Correction

(76) Inventors: Juen-Tien Peng, Chung Li (TW); Gin-Pao Lu, Cupertino, CA (US)

Correspondence Address: HDSL, 4331 STEVENS BATTLE LANE, FAIRFAX, VA, 22033, US

(21) Appl. No.: 11/740,899

(22) Filed: Apr. 26, 2007

(51) Int. Cl. G01R 31/08

(52) U.S. Cl. 370/244

(57) ABSTRACT

A real-time internet error correction method includes a transmitter side of a real-time internet connection adjusting it's transmitting speed periodically according to the real-time average internet error rate detected at a receiver side to reduce the quantity of packet loss. When the error rate received at transmitter side is greater than the standard set by the user, the transmitter side will automatically reduce its transmitting speed until the error rate once again fall below the standard. As a result, the method can prevent the situation when the real-time internet connection has high error rate, the transmitter side still send packets at full speed which will only result in more packet loss. Furthermore, the present invention further discloses an algorithm which can more precisely calculate the average real-time internet connection error rate.

### BACKGROUND OF THE INVENTION

1. Field of the Invention

The present invention relates to a real-time internet error correction, particularly to a correction which adjusts the transmitting speed according to the error rate to reduce packet loss.

2. Description of the Related Art

As the current technology grows rapidly, applications such as 3G mobile phones, real-time net TV and webcams rely on very mature connection technology to work. In order to provide better transmitting quality, the quantity of packet loss must be kept under certain level. As for the prior art, most vendor usually spend lots of effort on improving the hardware quality, however, it is not so effective against real-time connection since internet transmitting error is certainly unavoidable. In addition, not only the cost is high for improving the hardware, it also has the difficulties to implement massively. As no current technology can effectively solve the problem mentioned above, the present invention proposes a simple and cost-effective real-time internet error correction method which can greatly reduce the quantity of packet loss.

### SUMMARY OF THE INVENTION

The present invention is to provide a real-time internet error correction method, wherein the correction of the present invention reduces the quantity of packet loss by adjusting the transmitting speed during a real-time internet connection according to the error rate detected at receiver side. First, define a periodical time and a past duration. The receiver side will periodically detect the average real-time internet error rate for the past duration and report the result to transmitter side. Then the transmitter side will adjust its transfer speed according to the error rate. The receiver side and transmitter side can exist at same side at same time.

### BRIEF DESCRIPTION OF THE DRAWINGS

FIG. 1 is an illustration showing the structure of the present invention.

FIG. 2 is an illustration showing the algorithm for calculating the average error rate.

### DETAILED DESCRIPTION OF THE INVENTION

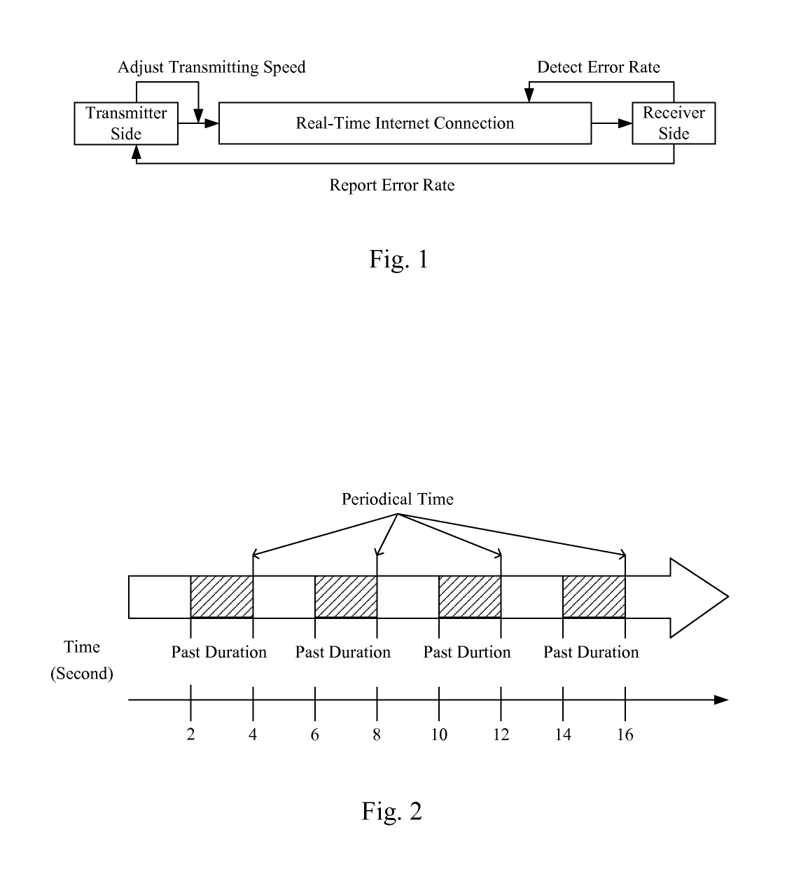

The present invention discloses a real-time internet error correction method, particular to a correction which reduces the quantity of packet loss by adjusting the transmitting speed. As shown in FIG. 1, in a real-time internet connection between a transmitter side and a receiver side, the receiver side will periodically detect the average error rate for the real-time internet connection and report to the transmitter side. When the transmitter side receives the average error rate, it will automatically adjust the transmitting speed according to the error rate. For example, if the real-time internet connect has high error rate which exceeds the standard set by the user, the transmitter side will reduce its transmitting speed until the error rate once again fall below the standard. In addition, the transmitter side and receiver side can exist at same side at same time.

The following is one of the preferred embodiments for the present invention. Assume within a real-time internet connection, the maximum transmitting speed for the transmitter side is 10 Mb/S and we set the error rate standard not exceeding 10%. When the real-time internet connection starts initially, the transmitter side will transfer its packet with full speed, which is 10 Mb/s. At the same time, the receiver side will start detect and calculate the average real-time internet error rate periodically and report the result to the transmitter side. If the result is greater than 10%, the transmitter side will automatically adjust its transmitting speed to 1 Mb/s. The speed will come back to 10 Mb/s once the transmitter side receives the error rate below 10%. This action will continue until the real-time internet connection terminated. In addition, the user can also set multiple standards. For example, when the error rate exceeds 30%, the transmitter runs at minimum speed, if the error rate is between 10% to 30%, the transmitter will run at medium speed and when the error rate is below 10%, the transmitter will run at full speed respectively.

In order to provide more accurate value for average real-time internet error rate, the present invention further discloses a calculating algorithm called moving average algorithm to calculate the average error rate in which the algorithm defines a periodical time and a past duration. Therefore, the receiver will only calculate the average for the error rate occurred during the past duration periodically instead of calculating the whole average from the beginning of the connection. As shown in FIG. 2 which demonstrates one of the preferred embodiments for the algorithm, if we define the periodical time as 4 seconds and past duration as 2 seconds, the receiver will detect and calculate the average real-time internet connection error rate for the past 2 seconds at every 4 seconds. This algorithm can provide more accurate real-time internet error rate and prevent a long duration of high or low error rate which effects the overall average rate. However, the past time can also be adjusted to a long duration of time or simply the whole connection time depends on users' preference. The real-time internet mentioned in the present invention also includes both LAN, WAN and any applications which require real-time connection applications.

Those embodiments described above are to clarify the present invention to enable the persons skilled in the art to understand, make and use the present invention. However, it is not intended to limit the scope of the present invention, and any equivalent modification and variation according to the spirit of the present invention is to be also included within the scope of the claims of the present invention.

What is claimed is:

1. A real-time internet error correction method, comprising:
at a real-time internet connection between a transmitter side and a receiver side, defining a periodical time and a past duration;
said receiver side periodically calculating an average real-time internet error rate for the past duration and reporting a result to said transmitter side; and
said transmitter side adjusting a transmitting speed thereof according to a value of error rate.

2. The real-time internet error correction method according to claim 1, wherein said transmitter side and said receiver side exist at same side at same time.

3. The real-time internet error correction method according to claim 1, wherein said real-time internet includes LAN, WAN and applications embedded with real-time connection technology.

4. The real-time internet error correction method according to claim 1, wherein said past time is a long duration of time or a whole connection time.
